(19) United States
(12) Patent Application Publication
(10) Pub. No.: US 2010/0176449 A1
(43) Pub. Date: Jul. 15, 2010

(54) SEMICONDUCTOR DEVICE AND METHOD FOR MANUFACTURING SAME

(75) Inventors: Tomoko Matsudai, Tokyo (JP); Norio Yasuhara, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/688,459

(22) Filed: Jan. 15, 2010

(30) Foreign Application Priority Data
Jan. 15, 2009 (JP) 2009-006880
Jan. 6, 2010 (JP) 2010-001153

(51) Int. Cl. H01L 29/78; H01L 21/336

(52) U.S. Cl. 257/335; 438/286; 438/306; 257/E21.417; 257/E29.256

(57) ABSTRACT

A semiconductor device, includes: a semiconductor layer including a first semiconductor region of a first conductivity type and a second semiconductor region of the first conductivity type, the second semiconductor region having a first conductivity type impurity concentration lower than a first conductivity type impurity concentration of the first semiconductor region; a source region of a second conductivity type provided on the first semiconductor region; a drain region of the second conductivity type provided on the second semiconductor region; an insulating film provided on the semiconductor layer between the source region and the drain region; a gate electrode provided on the insulating film; and a drift region of the second conductivity type provided in a surface side portion of the semiconductor layer between the gate electrode and the drain region, the drift region being in contact with the drain region and having a second conductivity type impurity concentration lower than a second conductivity type impurity concentration of the drain region.

### CROSS-REFERENCE TO RELATED APPLICATIONS

This application is based upon and claims the benefit of priority from the prior Japanese Patent Application No. 2009-006880, filed on Jan. 15, 2009 and the prior Japanese Patent Application No. 2010-001153, filed on Jan. 6, 2010; the entire contents of which are incorporated herein by reference.

### BACKGROUND OF THE INVENTION

1. Field of the Invention

The invention relates to a semiconductor device and a method for manufacturing the same.

2. Background Art

LDMOS (Lateral Diffusion Metal-Oxide-Semiconductor) structures are known in various breakdown voltage systems required for applications (for example, JP-A 2007-53257 (Kokai)). In recent years, fine processes and fine design rules similar to those of CMOS (Complementary Metal-Oxide-Semiconductor) devices have been increasingly applied to LDMOS devices to reduce the ON resistance and increase the speed. The application of fine design rules provides an LDMOS device with a short channel such as that of a CMOS device, enables downsizing of the entire device, allows the design of a low-voltage driven LDMOS, and permits circuit design of fine CMOS and LDMOS devices together on one chip.

### SUMMARY OF THE INVENTION

According to an aspect of the invention, there is provided a semiconductor device, including: a semiconductor layer including a first semiconductor region of a first conductivity type and a second semiconductor region of the first conductivity type, the second semiconductor region having a first conductivity type impurity concentration lower than a first conductivity type impurity concentration of the first semiconductor region; a source region of a second conductivity type provided on the first semiconductor region; a drain region of the second conductivity type provided on the second semiconductor region; an insulating film provided on the semiconductor layer between the source region and the drain region; a gate electrode provided on the insulating film; and a drift region of the second conductivity type provided in a surface side portion of the semiconductor layer between the gate electrode and the drain region, the drift region being in contact with the drain region and having a second conductivity type impurity concentration lower than a second conductivity type impurity concentration of the drain region.

According to another aspect of the invention, there is provided a method for manufacturing a semiconductor device, including: selectively performing ion implantation into a semiconductor layer using a mask to simultaneously form a first semiconductor region of a first conductivity type and a second semiconductor region of the first conductivity type in the semiconductor layer, the second semiconductor region having a first conductivity type impurity concentration lower than a first conductivity type impurity concentration of the first semiconductor region; forming a gate electrode on the semiconductor layer via an insulating film; forming a source region of a second conductivity type on the first semiconductor region; forming a drain region of the second conductivity type on the second semiconductor region at a side of the gate electrode opposite to the source region; and forming a drift region of the second conductivity type in a surface side portion of the semiconductor layer between the gate electrode and the drain region, the drift region being in contact with the drain region and having an impurity concentration lower than an impurity concentration of the drain region.

According to still another aspect of the invention, there is provided a method for manufacturing a semiconductor device, including: selectively performing ion implantation into a semiconductor layer using a mask to simultaneously form a first semiconductor region of a second conductivity type and a second semiconductor region of the second conductivity type in the semiconductor layer, the second semiconductor region having a second conductivity type impurity concentration higher than a second conductivity type impurity concentration of the first semiconductor region; performing ion implantation uniformly into an entire surface of the first semiconductor region and the second semiconductor region to simultaneously form a third semiconductor region of a first conductivity type on the first semiconductor region and a fourth semiconductor region of the first conductivity type on the second semiconductor region, the fourth semiconductor region having a first conductivity type impurity concentration lower than a first conductivity type impurity concentration of the third semiconductor region; forming a gate electrode on the semiconductor layer via an insulating film; forming a source region of the second conductivity type on the third semiconductor region; forming a drain region of the second conductivity type on the fourth semiconductor region at a side of the gate electrode opposite to the source region; and forming a drift region of the second conductivity type in a surface side portion of the semiconductor layer between the gate electrode and the drain region, the drift region being in contact with the drain region and having an impurity concentration lower than an impurity concentration of the drain region.

### BRIEF DESCRIPTION OF THE DRAWINGS

FIG. 1 is a schematic view showing the cross-sectional structure of main components of a semiconductor device according to embodiments of the invention;

FIG. 2 is a schematic view showing a first embodiment of an LDMOS in the semiconductor device;

FIGS. 3A to 3C are schematic views showing a method for manufacturing the LDMOS illustrated in FIG. 2;

FIGS. 4A to 4C are schematic views showing processes following FIG. 3C;

FIGS. 5A to 5C are schematic views showing processes following FIG. 4C;

FIGS. 6A to 6C are schematic views showing plane pattern examples of a mask used for ion implantation in the embodiments;

FIG. 7 is a schematic view showing a second embodiment of the LDMOS;

FIGS. 8A and 8B are schematic views showing a method for manufacturing the LDMOS illustrated in FIG. 7;

FIGS. 9A and 9B are schematic views showing processes following FIG. 8B;

FIGS. 10A and 10B are schematic views showing another method for manufacturing the LDMOS illustrated in FIG. 7;

FIGS. 11A and 11B are schematic views showing processes following FIG. 10B;

FIG. 12 is a schematic view showing an LDMOS of a third embodiment;

FIGS. 13A and 13B are schematic views showing a method for manufacturing the LDMOS illustrated in FIG. 12;

FIGS. 14A and 14B are schematic views showing another method for manufacturing the LDMOS illustrated in FIG. 12;

FIG. 15 is a schematic view showing still another embodiment of the LDMOS; and

FIG. 16 is a schematic view showing still another embodiment of the LDMOS.

### DETAILED DESCRIPTION OF THE INVENTION

Embodiments of the invention will now be described with reference to the drawings. Although a first conductivity type is a P-type and a second conductivity type is an N-type in the descriptions of the embodiments hereinbelow, the invention is practicable also when the first conductivity type is the N-type and the second conductivity type is the P-type.

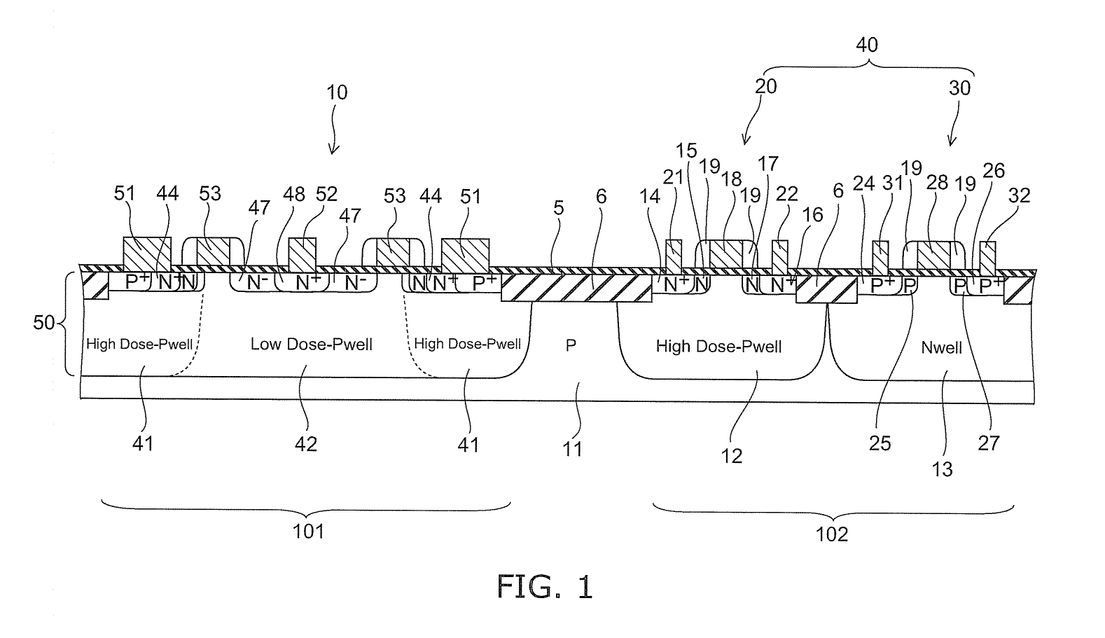

A semiconductor device according to this embodiment has a one-chip structure in which a FET (Field Effect Transistor) having an LDMOS (Lateral Diffusion Metal-Oxide-Semiconductor) structure and a FET having a CMOS (Complementary Metal-Oxide-Semiconductor) structure are provided together on the same substrate. FIG. 1 illustrates the cross-sectional structure of main components thereof.

An LDMOS 10 is formed in a first transistor formation region 101 of a substrate 11 of, for example, the P-type. A CMOS 40 is formed in a second transistor formation region 102 of the substrate 11. High-concentration P-type well regions 41 and a low-concentration P-type well region 42 are formed in the first transistor formation region 101 of the substrate 11. A semiconductor layer 50 including the high-concentration P-type well regions 41 and the low-concentration P-type well region 42 is formed in the first transistor formation region 101 of the substrate 11. A P-type well region 12 and an N-type well region 13 are formed in the second transistor formation region 102 of the substrate 11.

An insulating layer 6 having an STI (Shallow Trench Isolation) structure, for example, provides element separation between the P-type well region 12 and the N-type well region 13. The insulating layer 6 having the STI structure also provides the semiconductor layer 50 of the first transistor formation region 101 with element separation from the P-type well region 12 and the N-type well region 13.

The CMOS 40 includes an N-channel MOS 20 provided on the P-type well region 12 and a P-channel MOS 30 provided on the N-type well region 13.

An N⁺-type source region 14 and an N⁺-type drain region 16 are provided apart from each other in the top layer portion of the P-type well region 12. An N-type LDD (Lightly Doped Drain) region 15 having an N-type impurity concentration lower than that of the source region 14 is provided adjacent to the source region 14 in the top layer portion of the P-type well region 12. An N-type LDD region 17 having an N-type impurity concentration lower than that of the drain region 16 is provided adjacent to the drain region 16 in the top layer portion of the P-type well region 12.

A gate electrode 18 is provided on the P-type well region 12 between the LDD region 15 and the LDD region 17 via an insulating film 5. Side wall insulating films 19 are provided on the side walls of the gate electrode 18. The LDD region 15 and the LDD region 17 are positioned below the side wall insulating films 19.

A source electrode 21 is provided on the source region 14 and electrically connected to the source region 14 by, for example, ohmic contact. A drain electrode 22 is provided on the drain region 16 and electrically connected to the drain region 16 by, for example, ohmic contact.

When the desired gate voltage is applied to the gate electrode 18, an N-type channel is formed in the top layer portion of the P-type well region 12 below the gate electrode 18, and the source and the drain are electrically connected.

On the other hand, a P⁺-type source region 24 and a P⁺-type drain region 26 are provided apart from each other in the top layer portion of the N-type well region 13. A P-type LDD region 25 having a P-type impurity concentration lower than that of the source region 24 is provided adjacent to the source region 24 in the top layer portion of the N-type well region 13. A P-type LDD region 27 having a P-type impurity concentration lower than that of the drain region 26 is provided adjacent to the drain region 26 in the top layer portion of the N-type well region 13.

A gate electrode 28 is provided on the N-type well region 13 between the LDD region 25 and the LDD region 27 via the insulating film 5. The side wall insulating films 19 are provided on the side walls of the gate electrode 28. The LDD region 25 and the LDD region 27 are positioned below the side wall insulating films 19.

A source electrode 31 is provided on the source region 24 and electrically connected to the source region 24 by, for example, ohmic contact. A drain electrode 32 is provided on the drain region 26 and electrically connected to the drain region 26 by, for example, ohmic contact.

When the desired gate voltage is applied to the gate electrode 28, a P-type channel is formed in the top layer portion of the N-type well region 13 below the gate electrode 28, and the source and the drain are electrically connected.

The LDMOS 10 can be formed simultaneously with the formation of the CMOS 40 by utilizing the processes used for the CMOS formation.

The structure of the LDMOS 10 will now be described.

### First Embodiment

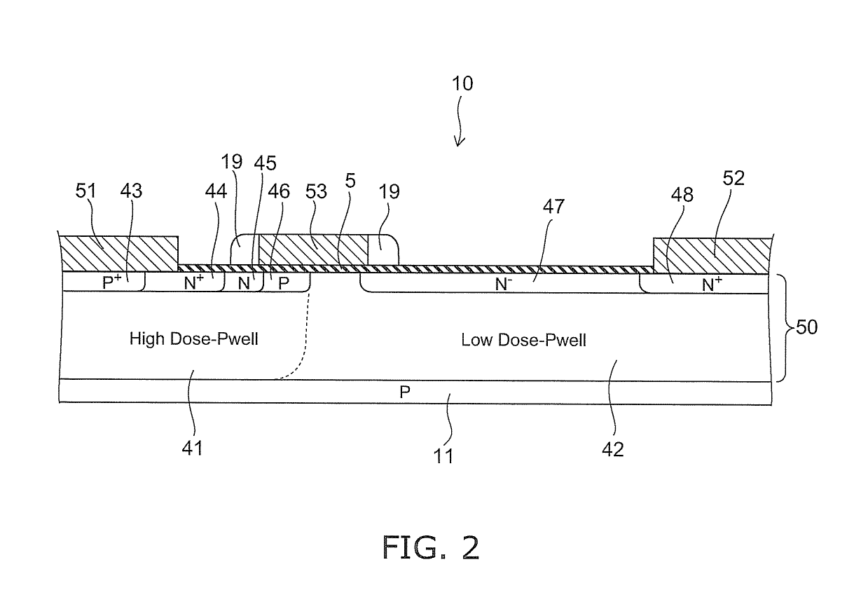

FIG. 2 is a schematic cross-sectional view of the LDMOS 10 according to a first embodiment of the invention.

Impurity diffusion regions are formed in the top layer portion of the semiconductor layer 50, including a P⁺-type contact region 43, an N⁺-type source region 44, an N-type LDD region 45, a P-type channel region 46, an N⁻-type drift region 47, and an N⁺-type drain region 48.

The semiconductor layer 50 includes the high-concentration P-type well region 41 and the low-concentration P-type well region 42 having a P-type impurity concentration lower than that of the high-concentration P-type well region 41. The high-concentration P-type well region 41 is formed by the same ion implantation process of the P-type well region 12 of the N-channel MOS 20 illustrated in FIG. 1. The high-concentration P-type well region 41 and the P-type well region 12 have substantially the same P-type impurity concentration and profile. The low-concentration P-type well region 42 also is formed by the same ion implantation process of the P-type well region 12 and the high-concentration P-type well region 41. The low-concentration P-type well region 42 has a P-type impurity concentration lower than those of the P-type well region 12 and the high-concentration P-type well region 41 by using a mask described below.

The contact region 43, the source region 44, the LDD region 45, and the channel region 46 are formed in the top layer portion of the high-concentration P-type well region 41. The drift region 47 and the drain region 48 are formed in the top layer portion of the low-concentration P-type well region 42.

The location of the flexion point of the P-type impurity concentration between the high-concentration P-type well region 41 and the low-concentration P-type well region 42 is schematically illustrated by the dotted line in FIG. 2. In other words, the effective P-type impurity concentration is higher on the source region 44 side of the dotted line than on the drain region 48 side. Conversely, the effective P-type impurity concentration is lower on the drain region 48 side of the dotted line than on the source region 44 side.

The LDD region 45, the channel region 46, and the drift region 47 are formed in order from the source region 44 side between the source region 44 and the drain region 48. The LDD region 45 contacts the source region 44. The channel region 46 contacts the LDD region 45 on the side opposite to the source region 44. The LDD region 45 has an N-type impurity concentration lower than those of the source region 44 and the drain region 48. The contact region 43 is provided on the side of the source region 44 opposite to the portion of the source region 44 contacting the LDD region 45, and the contact region 43 contacts the source region 44. The drift region 47 has an N-type impurity concentration lower than those of the source region 44 and the drain region 48 and contacts the drain region 48.

A source electrode 51 is provided on the contact region 43 and the source region 44. The source electrode 51 is electrically connected to the contact region 43 and the source region 44 by, for example, ohmic contact. The high-concentration P-type well region 41 has a source potential via the contact region 43. A drain electrode 52 is provided on the drain region 48. The drain electrode 52 is electrically connected to the drain region 48 by, for example, ohmic contact.

A gate electrode 53 is provided on the surface of the semiconductor layer 50 between the source region 44 and the drift region 47 via the insulating film 5. The side wall insulating films 19 are provided on the side walls of the gate electrode 53. The channel region 46 is positioned below the gate electrode 53, and the LDD region 45 is positioned below the side wall insulating film 19.

The impurity diffusion regions and the gate electrode 53 are formed, for example, in a striped pattern aligned in a direction going into the page. Alternatively, the contact region 43 and the source region 44 may be provided alternately or arranged at intervals in the direction going into the page.

When the desired gate voltage is applied to the gate electrode 53, an inversion layer is formed in the channel region 46; the source electrode 51 is electrically connected to the drain electrode 52 via the source region 44, the LDD region 45, the inversion layer, the drift region 47, and the drain region 48; and the state switches to an ON state. The threshold voltage may be adjusted by controlling the impurity concentration of the channel region 46.

By providing the LDMOS with the drift region 47 having a relatively low N-type impurity concentration, the drift region 47 is depleted to relax the electric field and the device breakdown voltage is maintained in the case where a reverse bias is applied between the drain and the source. The desired breakdown voltage can be realized by adjusting the N-type impurity concentration and the length in the horizontal direction of the drift region 47 according to the breakdown voltage necessary for the device.

In this embodiment, the CMOS 40 and the LDMOS 10 are formed in one chip on the same substrate 11. For example, the CMOS 40 may function as a driver circuit to drive the gate of the LDMOS 10. Because costs can be reduced by reducing the number of processes when manufacturing the CMOS 40 and the LDMOS 10 together on one chip, an LDMOS is formed utilizing the processes used to manufacture a CMOS.

In such a case, the well regions of the LDMOS are formed by the same ion implantation processes as the well regions of the CMOS. In the case where the impurity concentration of the well region of the CMOS is high, the device breakdown voltage of the LDMOS undesirably is determined by the breakdown voltage of the junction portion between the drain region and the high impurity concentration well region of the LDMOS. In other words, the breakdown voltage of the LDMOS is undesirably determined by the breakdown voltage setting of the CMOS. That is, because the breakdown voltage necessary for the LDMOS is often higher than that of the CMOS, it is not appropriate for the region below the drain region to be a high impurity concentration well region similar to that of the CMOS. Moreover, while the device breakdown voltage of an LDMOS is normally determined by the dose and the length of the drift region, the device breakdown voltage cannot be designed freely in a structure in which the breakdown voltage is determined by the region directly below the drain region.

Conversely, in this embodiment, the high-concentration P-type well region 41 and the low-concentration P-type well region 42 are formed in the LDMOS formation region and have relatively different impurity concentrations; and the drain region 48 of the LDMOS 10 is formed on the low-concentration P-type well region 42. Thereby, the decrease of the breakdown voltage of the junction portion between the drain region 48 and the low-concentration P-type well region 42 therebelow can be suppressed. In other words, the breakdown voltage of the LDMOS 10 is not undesirably determined by the breakdown voltage of the CMOS 40, and the desired breakdown voltage can be realized higher than that of the CMOS 40 by adjusting the N-type impurity concentration and the length in the horizontal direction of the drift region 47.

Further, punch-through due to the application of a reverse bias can be suppressed by providing the high-concentration P-type well region 41 having a relatively high impurity concentration below the source region 44 side of the LDMOS 10.

Although the impurity concentration flexion point (illustrated by the dotted line) between the high-concentration P-type well region 41 and the low-concentration P-type well region 42 is positioned below the gate electrode 53 in the examples illustrated in FIG. 1 and FIG. 2, the flexion point is not limited thereto and may be positioned, for example, below the drift region 47. Restated, it is sufficient that the high-concentration P-type well region 41 of the high impurity concentration designed for the CMOS does not contact the drain region 48.

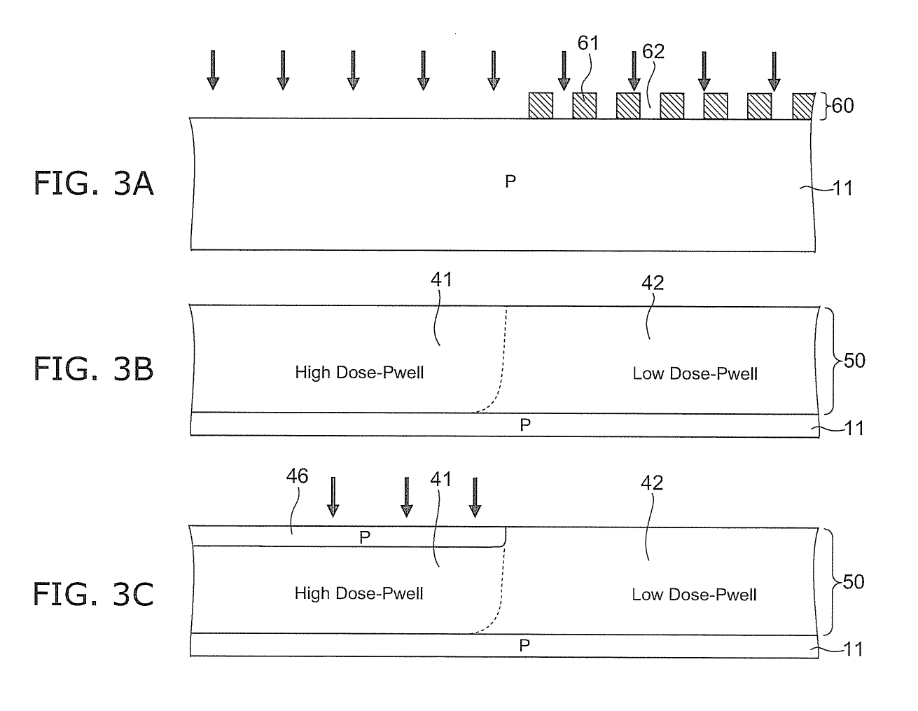

The method for manufacturing the LDMOS 10 will now be described with reference to FIGS. 3A to 5C.

First, a P-type impurity is introduced into the substrate 11 by ion implantation to simultaneously form the high-concentration P-type well region 41 and the low-concentration P-type well region 42. Specifically, ion implantation is performed using a mask 60 as illustrated in FIG. 3A.

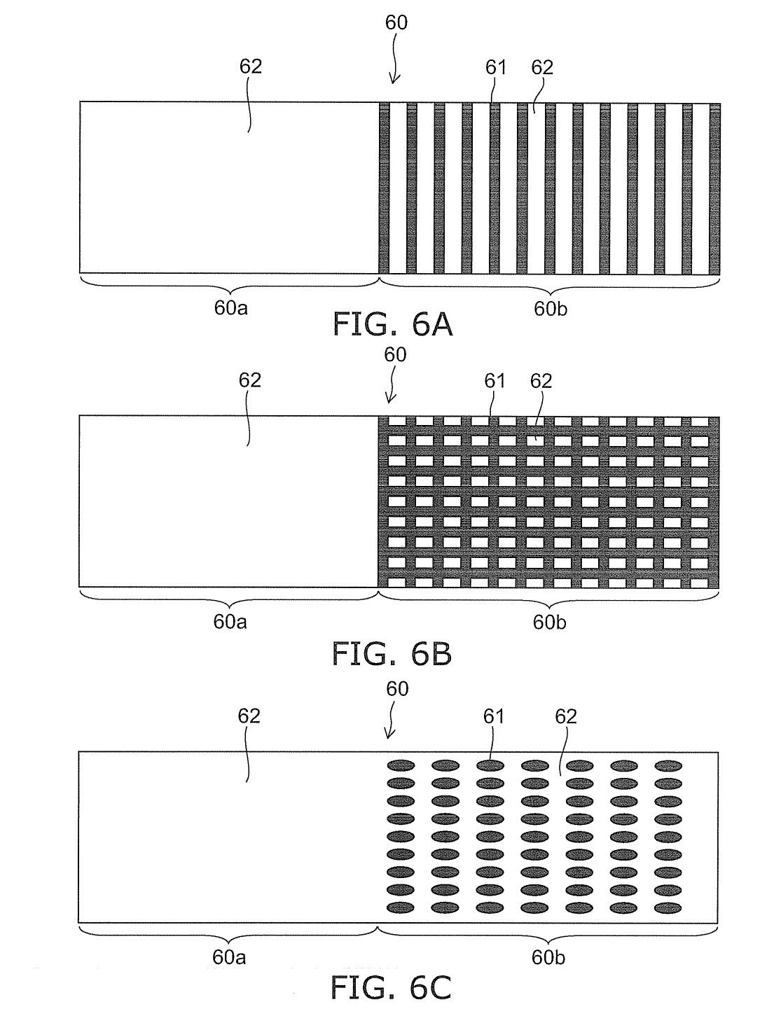

FIG. 6A is a plan view of the mask 60. The mask 60 includes a first opening formation region 60a and a second opening formation region 60b. The second opening formation region 60b has an opening ratio per unit surface area lower than that of the first opening formation region 60a. Shielding portions 61 are formed, for example, in a striped configuration in the second opening formation region 60b. The other portions of the second opening formation region 60b are openings 62. The shielding portion pattern is not limited to a striped configuration and may be a lattice configuration as illustrated in FIG. 6B or a multiple island configuration as illustrated in FIG. 6C.

The dose of the ion implantation is substantially uniform in the surface direction. The ion implantation is performed using the mask 60. Thereby, the amount of ion implantation into the portion below the second opening formation region 60b is relatively low, and the amount of ion implantation into the portion below the widely opened first opening formation region 60a adjacent to the second opening formation region 60b is relatively high. In other words, as illustrated in FIG. 3B, the high-concentration P-type well region 41 having a relatively high impurity concentration and the low-concentration P-type well region 42 having a relatively low impurity concentration can be formed simultaneously by one ion implantation process.

The position of the impurity concentration flexion point (illustrated by the dotted line in FIG. 3B) where the P-type impurity concentration greatly changes between the high-concentration P-type well region 41 and the low-concentration P-type well region 42 is proximal to the boundary between the second opening formation region 60b and the first opening formation region 60a of the mask 60 illustrated in FIG. 6A described above.

The ion implantation recited above is performed multiple times (in multiple stages) with different acceleration voltages and to different depths. After the ion implantation, heat treatment is performed to activate and diffuse the implanted impurity in the substrate 11. Accordingly, each of the high-concentration P-type well region 41 and the low-concentration P-type well region 42 has multiple impurity concentration peaks in the film thickness direction. Because the high-concentration P-type well region 41 and the low-concentration P-type well region 42 are formed by the same ion implantation process, the acceleration energy also is the same; and the high-concentration P-type well region 41 and the low-concentration P-type well region 42 have impurity concentration peaks at substantially the same depth.

The P-type well region 12 of the N-channel MOS 20 of the CMOS 40 illustrated in FIG. 1 also is formed simultaneously with the ion implantation forming the high-concentration P-type well region 41 and the low-concentration P-type well region 42. Similarly to the high-concentration P-type well region 41 of the LDMOS 10, the P-type well region 12 is not covered with shielding portions. Therefore, the high-concentration P-type well region 41 of the LDMOS 10 and the P-type well region 12 of the N-channel MOS 20 have substantially the same relatively high impurity concentration.

During the ion implantation of the P-type impurity recited above, the portion of the substrate 11 forming the P-channel MOS 30 is covered with a mask, and the P-type impurity is not implanted. Prior to or after performing the P-type impurity implantation recited above, the N-type well region 13 of the P-channel MOS 30 is formed by using a mask to cover the portions of the substrate 11 other than where the N-type well region 13 is formed and by performing implantation of an N-type impurity.

By ion implantation using the mask 60 according to this embodiment as described above, the low impurity concentration well region for the LDMOS can be simultaneously formed without changing the well region concentration conditions of the CMOS in which fine design rules are applied. In other words, two well regions having relatively different effective impurity concentrations can be formed for the LDMOS during the forming of the well region of the CMOS. As a result, the CMOS process can be applied to manufacture the CMOS and the LDMOS having a breakdown voltage higher than that of the CMOS together on one chip; additional processes are not necessary for the LDMOS; and costs can be reduced. Moreover, the LDMOS does not depend on the breakdown voltage setting of the CMOS, and the desired high breakdown voltage design is possible.

After forming the high-concentration P-type well region 41 and the low-concentration P-type well region 42, the P-type region 46 forming the channel region of the LDMOS is formed in the top layer portion of the high-concentration P-type well region 41 by selective ion implant and subsequent heat treatment as illustrated in FIG. 3C. The P-type impurity concentration of the P-type region 46 is set to obtain the desired gate threshold. The P-type LDD regions 25 and 27 of the P-channel MOS 30 of the CMOS 40 also are formed simultaneously with the forming of the P-type region 46.

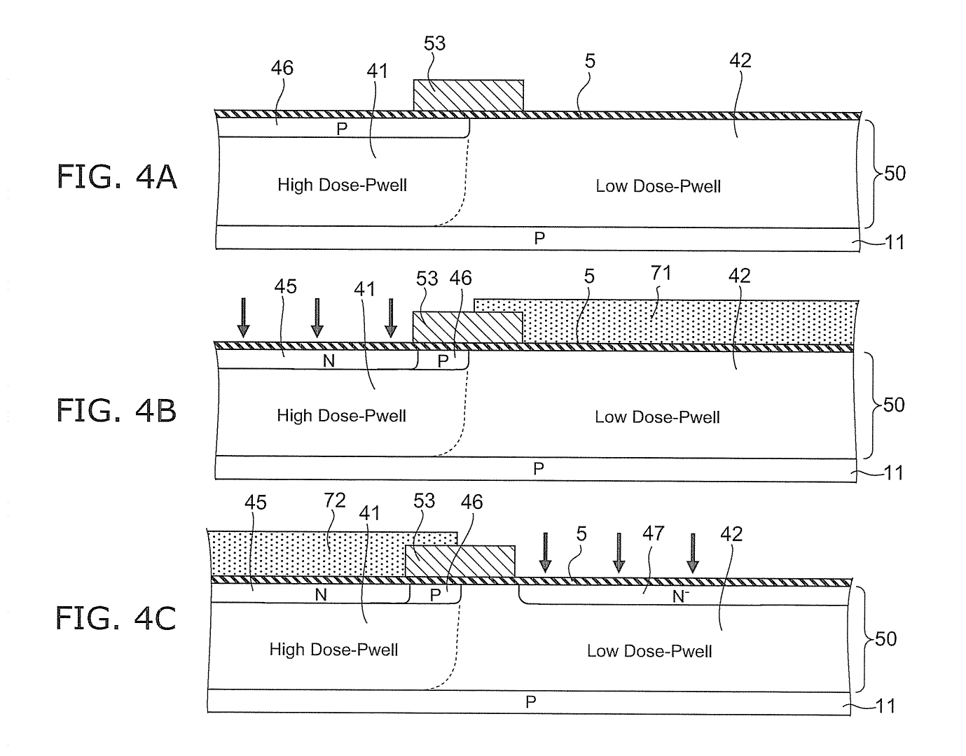

Then, as illustrated in FIG. 4A, the insulating film 5 is formed on the surface of the semiconductor layer 50. A gate electrode material is formed on the insulating film 5 and subsequently patterned into the desired configuration to form the gate electrode 53 by leaving the gate electrode material in the desired position. At this time, the insulating film 5 and the gate electrodes 18 and 28 of the CMOS 40 also are formed simultaneously.

Continuing as illustrated in FIG. 4B, a mask 71 is provided to cover the low-concentration P-type well region 42 and a portion of the gate electrode 53 on the drain side. In this state, the N-type region 45 forming the LDD region is formed by implanting an N-type impurity into the P-type region 46 by ion implantation. The boundary (the PN junction portion) between the N-type region 45 and the P-type region 46 is positioned proximally to the end portion of the gate electrode 53 on the source side. At this time, the LDD regions 15 and 17 of the N-channel MOS 20 of the CMOS 40 also are formed simultaneously.

Then, as illustrated in FIG. 4C, a mask 72 is provided to cover the portion where the N-type region 45 is formed and a portion of the gate electrode 53 on the source side. In this state, an N⁻-type region 47 forming the drift region is formed by implanting an N-type impurity into the top layer portion of the low-concentration P-type well region 42 by ion implantation.

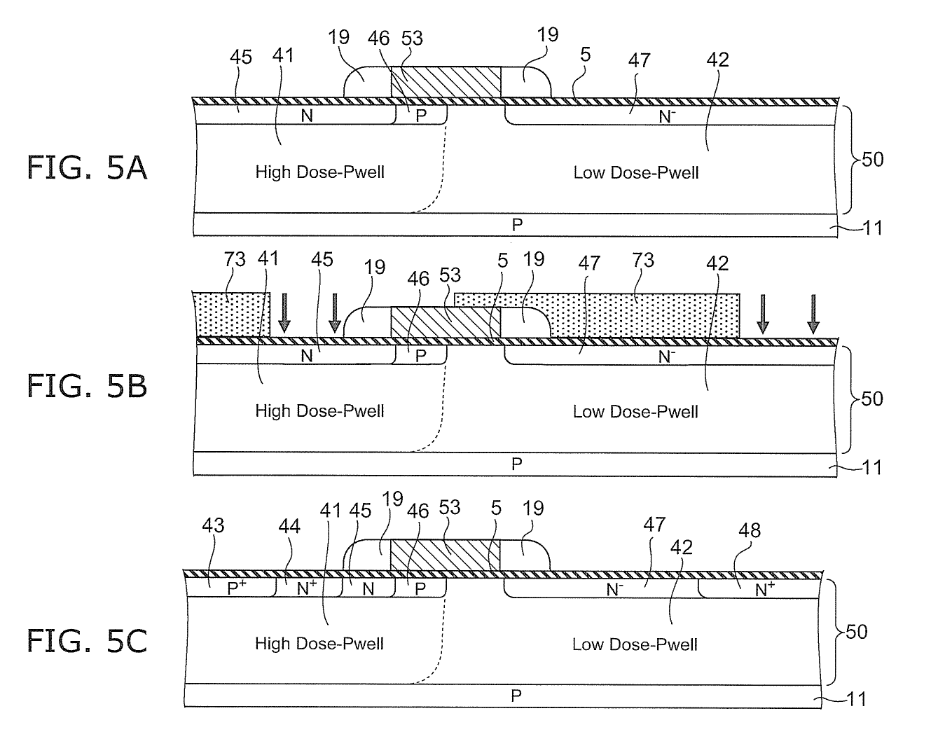

Continuing as illustrated in FIG. 5A, the side wall insulating films 19 are formed on both side walls of the gate electrode 53 along the gate length direction. At this time, the side wall insulating films 19 are formed simultaneously on the side walls of the gate electrodes 18 and 28 of the CMOS 40.

Then, as illustrated in FIG. 5B, a mask 73 is provided to cover a portion of the N-type region 45, a portion of the gate electrode 53 on the N⁻-type region 47 side, the side wall insulating film 19 on the N⁻-type region 47 side, and a portion of the N⁻-type region 47. The source region 44 and the drain region 48 are formed as illustrated in FIG. 5C by implanting an N-type impurity by ion implantation into the N-type region 45 and the N⁻-type region 47 not covered with the mask 73. At this time, the source region 14 and the drain region 16 of the N-channel MOS 20 of the CMOS 40 also are formed simultaneously.

Subsequently, the contact region 43 is formed in the source region 44 by covering the necessary portions with a not-illustrated mask and performing selective ion implantation with a P-type impurity. At this time, the source region 24 and the drain region 26 of the P-channel MOS 30 of the CMOS 40 also are formed simultaneously.

Thereafter, the source electrodes 51, 21, and 31 and the drain electrodes 52, 22, and 32 of the LDMOS 10 and the CMOS 40 are formed simultaneously, and the structure illustrated in FIG. 1 is obtained.

### Second Embodiment

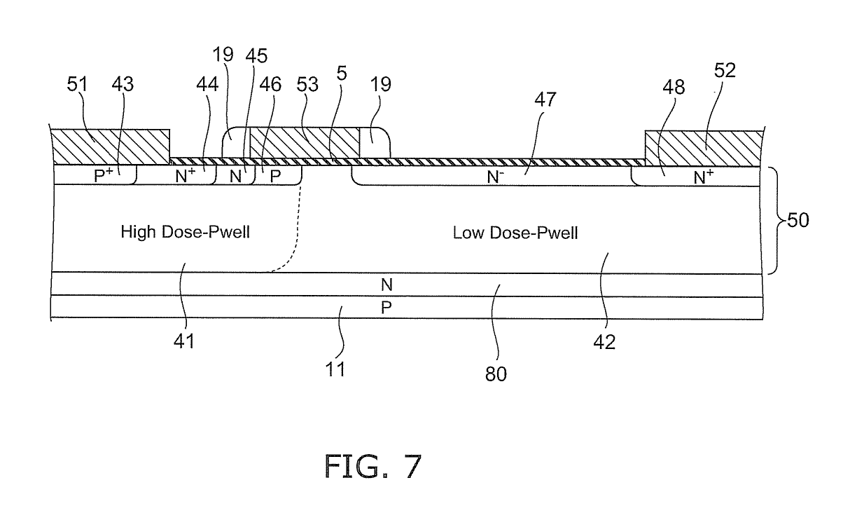

FIG. 7 is a schematic view illustrating a second embodiment of the LDMOS 10. Components similar to those of the first embodiment recited above are marked with like reference numerals, and a detailed description is omitted.

In this embodiment, an N-type layer 80 is provided on the substrate 11 supporting the semiconductor layer 50. The semiconductor layer 50 including the high-concentration P-type well region 41 and the low-concentration P-type well region 42 is provided on the N-type layer 80.

The N-type layer 80 is connected to any electrode in a device terminal via an N⁺ layer (not illustrated) having a relatively high impurity concentration. Thereby, a structure is provided in which the device portions above the N-type layer 80 are surrounded by the N-type layer 80 provided with any potential and separated by the N-type layer 80 from the potential of the substrate 11 side.

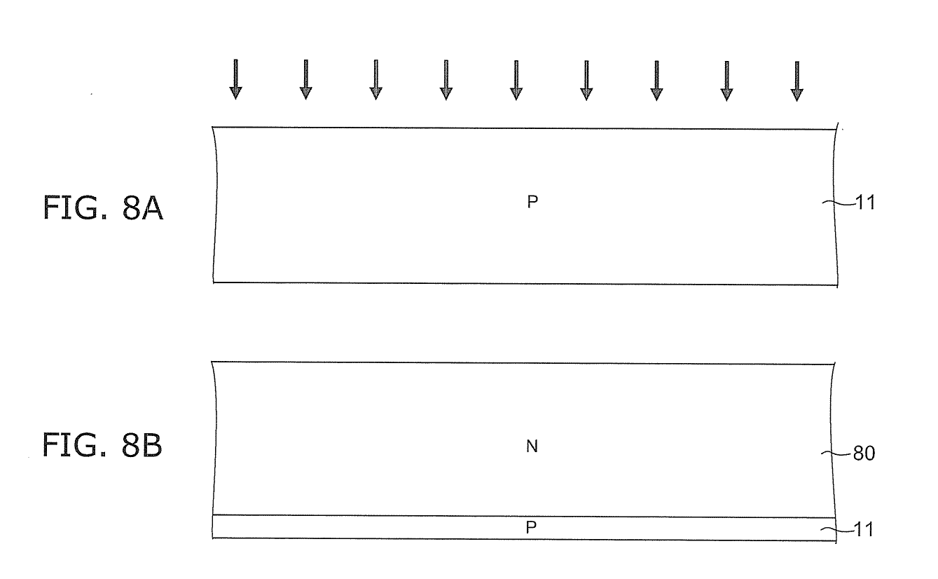

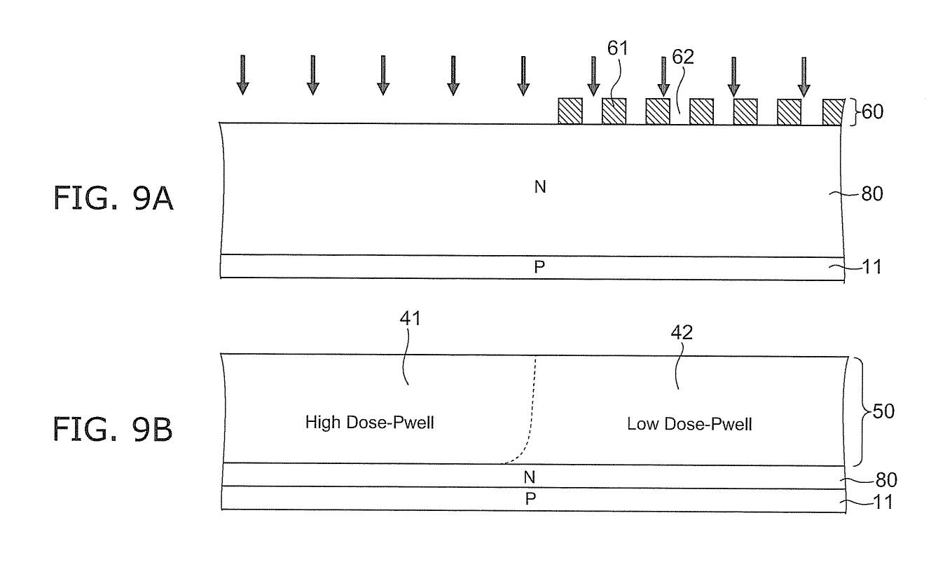

FIGS. 8A to 9B illustrate the method for manufacturing the LDMOS of this embodiment.

First, the N-type layer 80 illustrated in FIG. 8B is formed by introducing an N-type impurity into the substrate 11 by ion implantation as illustrated in FIG. 8A and subsequently performing heat treatment. A mask is not used during the ion implantation, and the impurity is introduced with a uniform dose in the surface direction of the substrate 11.

Then, a P-type impurity is introduced into the N-type layer 80 by ion implantation to simultaneously form the high-concentration P-type well region 41 and the low-concentration P-type well region 42. Specifically, ion implantation is performed similarly to that of the first embodiment described above using the mask 60 illustrated in FIG. 9A.

By performing ion implantation into the substrate 11 using the mask 60, it is possible to use one ion implantation process to simultaneously form the high-concentration P-type well region 41 having the relatively high impurity concentration and the low-concentration P-type well region 42 having the relatively low impurity concentration. At this time as well, the P-type well region 12 of the N-channel MOS 20 of the CMOS 40 illustrated in FIG. 1 also is formed simultaneously.

Thereafter, processes similar to those including and subsequent to FIG. 3C described above are performed to obtain the structure illustrated in FIG. 7.

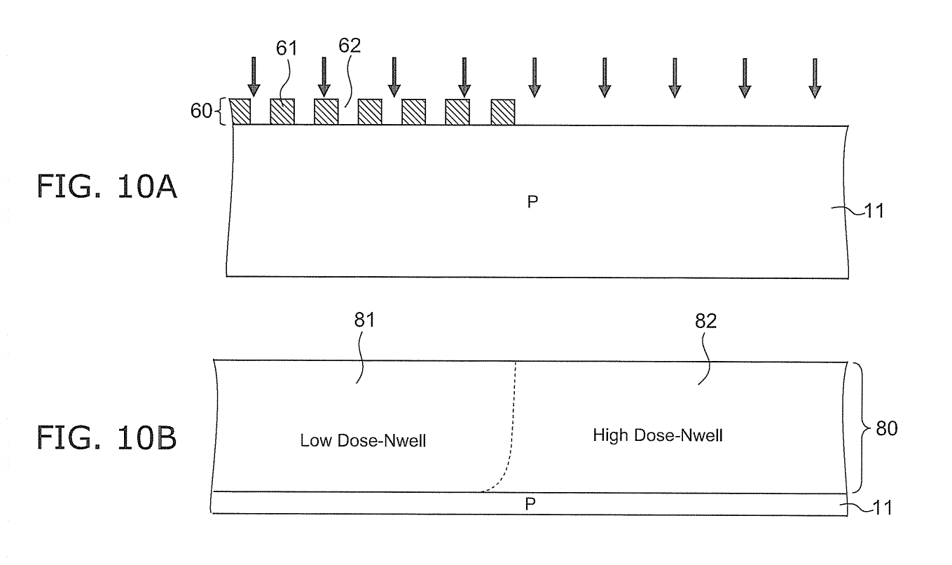

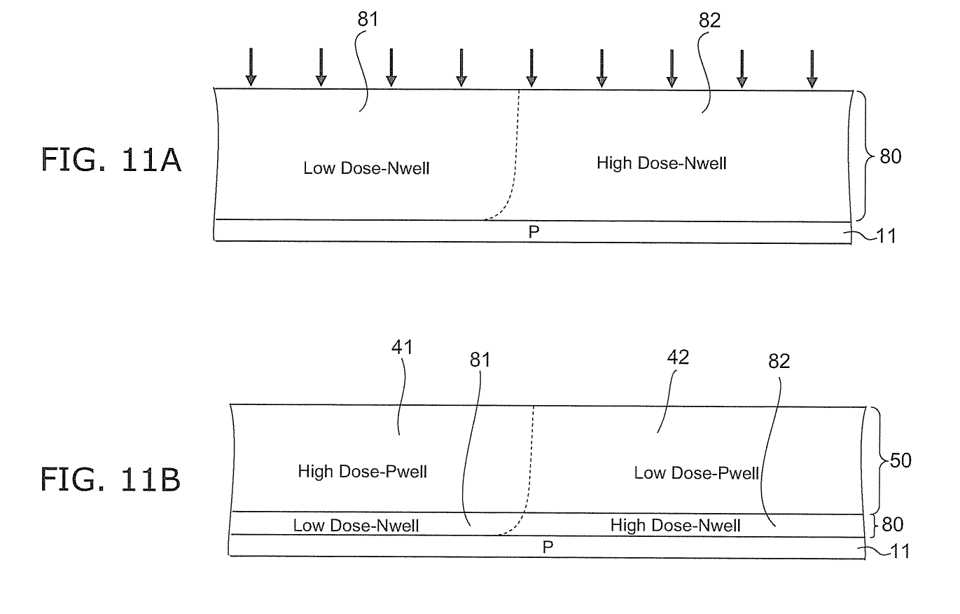

The method illustrated in FIGS. 10A to 11B may be used instead of the method of FIGS. 8A to 9B.

In this method, first, an N-type impurity is introduced into the substrate 11 by ion implantation to form the N-type layer 80 including a low-concentration N-type region 81 and a high-concentration N-type region 82. Specifically, ion implantation is performed using the mask 60 described above as illustrated in FIG. 10A.

By performing ion implantation into the substrate 11 using the mask 60, it is possible to use one ion implantation step to simultaneously form the low-concentration N-type region 81 having the relatively low impurity concentration and the high-concentration N-type region 82 having the relatively high impurity concentration.

Then, as illustrated in FIG. 11A, a P-type impurity is introduced into the N-type layer 80 with a uniform dose in the surface direction by ion implantation without using a mask. By subsequently performing heat treatment, the high-concentration P-type well region 41 is formed on the low-concentration N-type region 81, and the low-concentration P-type well region 42 is formed on the high-concentration N-type region 82 as illustrated in FIG. 11B.

In other words, although the dose of the P-type impurity implanted into the N-type layer 80 is uniform in the surface direction, the portion of the low-concentration N-type region 81 in which the P-type impurity is introduced has a relatively high P-type impurity concentration; and the portion of the high-concentration N-type region 82 in which the P-type impurity is introduced has a relatively low P-type impurity concentration.

In the second embodiment described above as well, the low impurity concentration well region for the LDMOS can be simultaneously formed without changing the well region concentration conditions of the CMOS in which fine design rules are applied. In other words, two well regions having relatively different effective impurity concentrations can be formed for the LDMOS during the forming of the well region of the CMOS. As a result, the CMOS process can be applied to manufacture the CMOS and the LDMOS having a breakdown voltage higher than that of the CMOS together on one chip; additional processes are not necessary for the LDMOS; and costs can be reduced. Moreover, the LDMOS does not depend on the breakdown voltage setting of the CMOS, and the desired high breakdown voltage design is possible.

### Third Embodiment

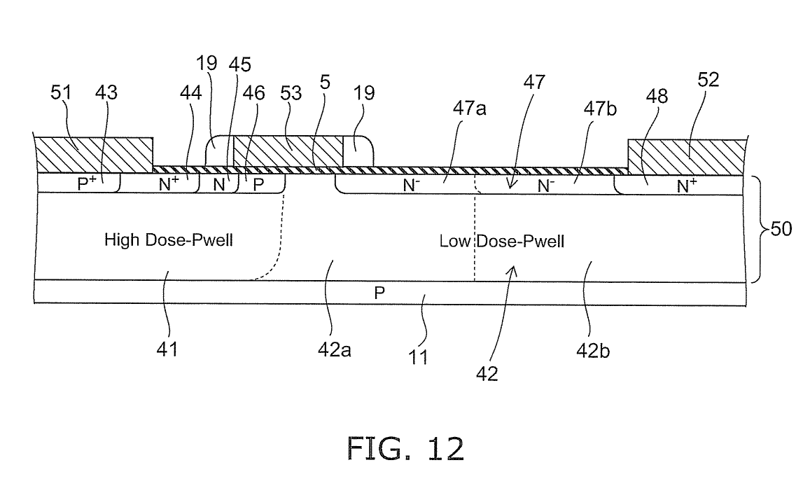

Next, FIG. 12 is a schematic cross-sectional view of an LDMOS according to a third embodiment of the invention.

In this embodiment, the low-concentration P-type well region 42 further includes two regions (a first region 42a and a second region 42b).

The first region 42a is provided on the high-concentration P-type well region 41 side and contacts a portion 47a of the drift region 47 on the gate electrode 53 side. The second region 42b is provided on the side of the first region 42a opposite to the high-concentration P-type well region 41 and contacts the drain region 48 and a portion 47b of the drift region 47 on the drain region 48 side. The second region 42b has a P-type impurity concentration lower than that of the first region 42a.

The drift region 47 is formed by implanting N-type impurity ions into the surface of the first region 42a and the second region 42b and subsequently performing heat treatment. Although the dose of the N-type impurity ions is substantially uniform in the surface direction of the first region 42a and the second region 42b, the first region 42a has a higher P-type impurity concentration than that of the second region 42b; and therefore, the N-type impurity regions (two portions 47a and 47b) having relatively different effective impurity concentrations are formed in the drift region 47.

The portion 47a provided above and in contact with the first region 42a has an N-type impurity concentration relatively lower than that of the portion 47b provided above and in contact with the second region 42b.

By using a relatively low impurity concentration in the portion 47a of the drift region 47 on the gate electrode 53 side, the portion 47a completely depletes in the OFF state (when a voltage equal to or greater than the threshold of the gate electrode 53 is not applied), and a high OFF breakdown voltage can be obtained.

By using a relatively high impurity concentration in the portion 47b of the drift region 47 on the drain region 48 side, the depletion of the portion 47b can be suppressed when a full bias equal to or greater than the threshold of the gate electrode 53 is applied, and a high ON breakdown voltage can be obtained. The semiconductor device according to this embodiment is suitable for, for example, a system power source in which a high ON breakdown voltage is necessary.

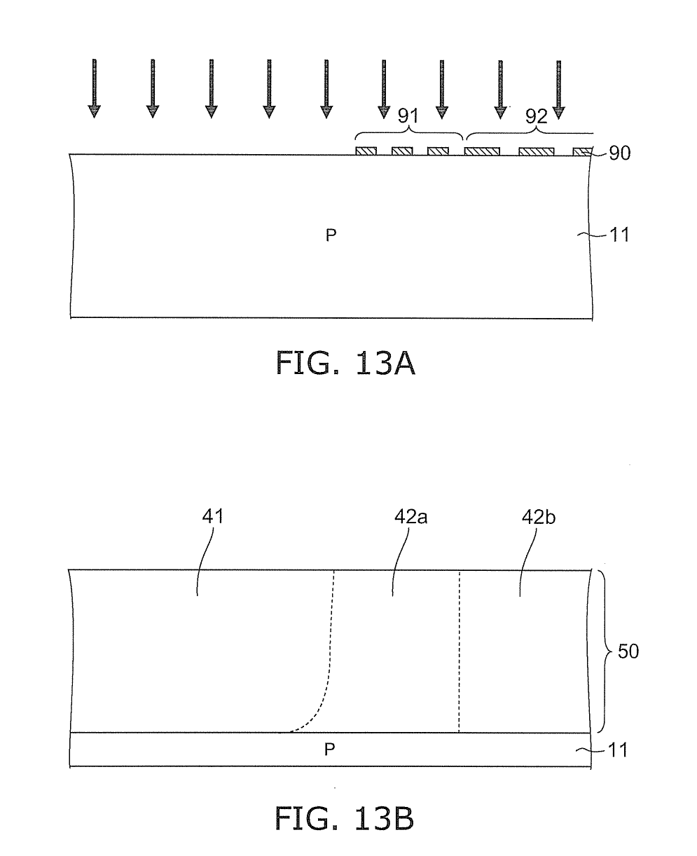

FIGS. 13A and 13B are schematic views illustrating the method for forming the high-concentration P-type well region 41 and the low-concentration P-type well region 42 of this embodiment.

The high-concentration P-type well region 41 and the low-concentration P-type well region 42 are formed by performing ion implantation of the P-type impurity into the substrate 11 using a mask 90 as illustrated in FIG. 13A.

The mask 90 includes a first opening formation region and a second opening formation region. The first opening formation region is open substantially over the entire surface, and the high-concentration P-type well region 41 is formed there below.

The second opening formation region includes light shielding portions formed, for example, in a striped configuration, lattice configuration, or island configuration similarly to the mask described above referring to FIGS. 6A to 6C. The second opening formation region has an opening ratio per unit surface area lower than that of the first opening formation region. The second opening formation region includes a first region 91 and a second region 92. The first region 91 is adjacent to the first opening formation region. The second region 92 is positioned on the side of the first region 91 opposite to the first opening formation region and has an opening ratio per unit surface area lower than that of the first region 91.

Therefore, the first region 42a having a relatively high P-type impurity concentration is formed below the first region 91 of the mask 90 having the relatively high opening ratio; and the second region 42b having the relatively low P-type impurity concentration is formed below the second region 92 of the mask 90 having the relatively low opening ratio (FIG. 13B).

In other words, in this embodiment, it is possible to use the same ion implantation process to simultaneously form the high-concentration P-type well region 41, the first region 42a having a P-type impurity concentration lower than that of the high-concentration P-type well region 41, and the second region 42b having a P-type impurity concentration lower than that of the first region 42a.

Then, by evenly implanting an N-type impurity into the surface of the first region 42a and the second region 42b, the drift region 47 can be obtained to include the portions 47a and 47b having relatively different effective N-type impurity concentrations.

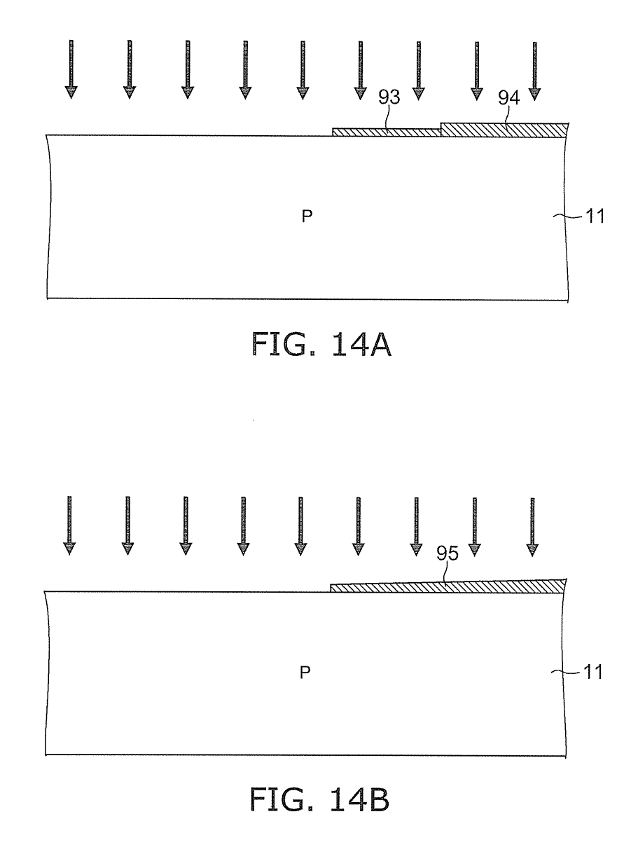

Masks 93 and 94 having relatively different film thicknesses as illustrated in FIG. 14A may be used to simultaneously form the first region 42a and the second region 42b having relatively different P-type impurity concentrations. The mask 94 has a film thickness thicker than the mask 93. The acceleration voltage may be controlled such that the P-type impurity ions pass through the masks 93 and 94 and enter into the substrate 11.

The ions implanted into the substrate 11 by passing through the mask 94 having the relatively thick film thickness have an implantation amount relatively lower than that of the ions implanted into the substrate 11 by passing through the mask 93 having the relatively thin film thickness. As a result, the first region 42a having the relatively high P-type impurity concentration is formed below the mask 93; and the second region 42b having the relatively low P-type impurity concentration is formed below the mask 94.

Also, as illustrated in FIG. 14B, a mask 95 may be used in which the film thickness gradually increases from the first region to the second region. The region having the relatively high P-type impurity concentration is formed below the portion of the mask 95 having the relatively thin film thickness; and the region having the relatively low P-type impurity concentration is formed below the portion of the mask 95 having the relatively thick film thickness. In the case where the mask 95 is used, it is possible to form a structure in which the P-type impurity concentration gradually decreases from the end of the first region 42a to the end of the second region 42b.

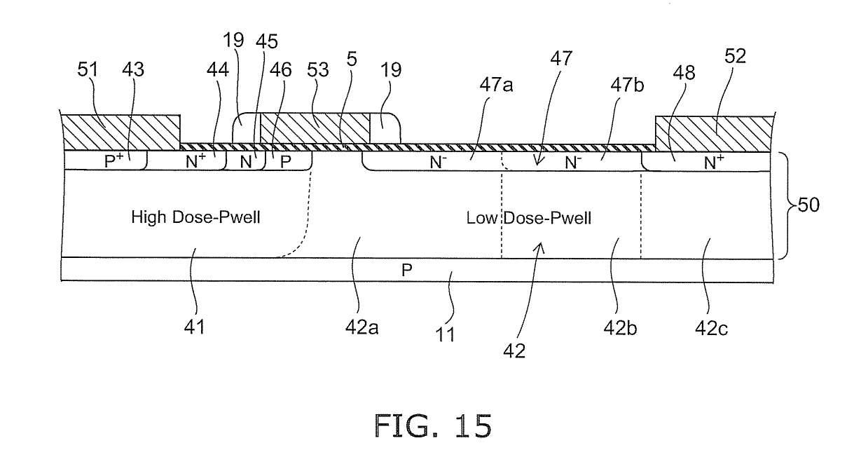

As illustrated in FIG. 15, the low-concentration P-type well region 42 may be divided into three regions (the first region 42a, the second region 42b, and a third region 42c).

The first region 42a is provided on the high-concentration P-type well region 41 side and contacts the portion 47a of the drift region 47 on the gate electrode 53 side. The second region 42b is provided on the side of the first region 42a opposite to the high-concentration P-type well region 41 and contacts the portion 47b of the drift region 47 on the drain region 48 side. The third region 42c is provided below and in contact with the drain region 48.

The inequality Qd1>Qd2>Qd3 holds, where Qd1 is the P-type impurity concentration of the first region 42a, Qd2 is the P-type impurity concentration of the second region 42b, and Qd3 is the P-type impurity concentration of the third region 42c.

The drift region 47 is formed by implanting N-type impurity ions into the surface of the first region 42a and the second region 42b and subsequently performing heat treatment. Although the dose of the N-type impurity ions is substantially uniform in the surface direction of the first region 42a and the second region 42b, the first region 42a has a higher P-type impurity concentration than that of the second region 42b; and therefore, the two portions 47a and 47b having relatively different effective N-type impurity concentrations are formed in the drift region 47.

In other words, the portion 47a provided above and in contact with the first region 42a has an impurity concentration relatively lower than that of the portion 47b provided above and in contact with the second region 42b.

By using a relatively low impurity concentration in the portion 47a of the drift region 47 on the gate electrode 53 side, the portion 47a completely depletes in the OFF state (when a voltage equal to or greater than the threshold of the gate electrode 53 is not applied), and a high OFF breakdown voltage can be obtained.

By using a relatively high impurity concentration in the portion 47b of the drift region 47 on the drain region 48 side, the depletion of the portion 47b can be suppressed when a full bias equal to or greater than the threshold of the gate electrode is applied, and a high ON breakdown voltage can be obtained.

Because the third region 42c below the drain region 48 in this embodiment has an impurity concentration even lower than that of the second region 42b, a decrease of the breakdown voltage of the junction portion between the drain region 48 and the third region 42c can be suppressed even further.

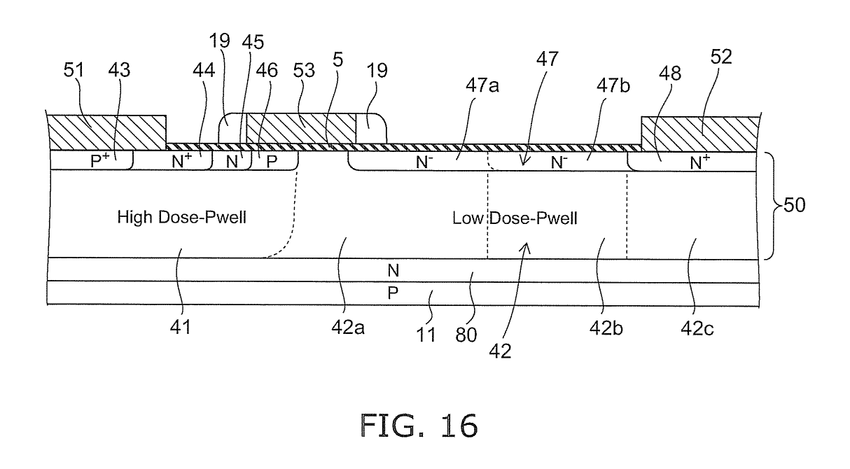

This embodiment is applicable also in the structure of the second embodiment illustrated in FIG. 7 described above. FIG. 16 illustrates such a structure.

In the case where the portion between the N-type layer 80 and the drain region 48 having a relatively high impurity concentration also has a high impurity concentration, there is a risk that punch-through may occur in the drain region 48 and the N-type layer 80 and reduce the breakdown voltage.

By further reducing the impurity concentration of the third region 42c and providing the third region 42c between the drain region 48 and the N-type layer 80 in the structure of FIG. 16, the punch-through recited above is suppressed, and a high breakdown voltage can be obtained.

Hereinabove, exemplary embodiments of the invention are described with reference to specific examples. However, the invention is not limited thereto. Various modifications are possible based on the technological spirit of the invention.

Although silicon, for example, may be used as the semiconductor material, the invention is not limited thereto, and other semiconductor materials may be used. Further, the semiconductors are not limited to single elements, and compound semiconductors may be used.

1. A semiconductor device, comprising:
a semiconductor layer including a first semiconductor region of a first conductivity type and a second semiconductor region of the first conductivity type, the second semiconductor region having a first conductivity type impurity concentration lower than a first conductivity type impurity concentration of the first semiconductor region;
a source region of a second conductivity type provided on the first semiconductor region;
a drain region of the second conductivity type provided on the second semiconductor region;
an insulating film provided on the semiconductor layer between the source region and the drain region;
a gate electrode provided on the insulating film; and
a drift region of the second conductivity type provided in a surface side portion of the semiconductor layer between the gate electrode and the drain region, the drift region being in contact with the drain region and having a second conductivity type impurity concentration lower than a second conductivity type impurity concentration of the drain region.

2. The device according to claim 1, wherein the drift region is provided on the second semiconductor region.

3. The device according to claim 1, wherein the second semiconductor region includes:
a first region provided at the first semiconductor region side to contact a portion of the drift region at the gate electrode side; and
a second region having a first conductivity type impurity concentration lower than a first conductivity type impurity concentration of the first region, the second region being in contact with a portion of the drift region at the drain region side.

4. The device according to claim 3, wherein a portion of the drift region at the drain region side has an impurity concentration higher than an impurity concentration of a portion of the drift region at the gate electrode side.

5. The device according to claim 3, wherein the second semiconductor region further includes a third region provided below the drift region, the third region being in contact with the drift region and having a first conductivity type impurity concentration lower than a first conductivity type impurity concentration of the second region.

6. The device according to claim 1, further comprising
a substrate supporting the semiconductor layer, and
a second semiconductor layer provided between the substrate and the semiconductor layer to separate the semiconductor layer from a potential of the substrate.

7. The device according to claim 1, wherein the first semiconductor region and the second semiconductor region have first conductivity type impurity concentration peaks at substantially the same depth.

8. The device according to claim 1, further comprising:
a substrate including a first transistor formation region and a second transistor formation region, the first transistor formation region and the second transistor formation region being separated,
the first semiconductor region and the second semiconductor region being provided in the first transistor formation region of the substrate,
a third semiconductor region of the first conductivity type being provided in the second transistor formation region of the substrate, the third semiconductor region having substantially the same first conductivity type impurity concentration as the first semiconductor region,
a field effect transistor of a second conductivity channel type being provided on the third semiconductor region.

9. A method for manufacturing a semiconductor device, comprising:
selectively performing ion implantation into a semiconductor layer using a mask to simultaneously form a first semiconductor region of a first conductivity type and a second semiconductor region of the first conductivity type in the semiconductor layer, the second semiconductor region having a first conductivity type impurity concentration lower than a first conductivity type impurity concentration of the first semiconductor region;
forming a gate electrode on the semiconductor layer via an insulating film;
forming a source region of a second conductivity type on the first semiconductor region;
forming a drain region of the second conductivity type on the second semiconductor region at a side of the gate electrode opposite to the source region; and
forming a drift region of the second conductivity type in a surface side portion of the semiconductor layer between the gate electrode and the drain region, the drift region being in contact with the drain region and having an impurity concentration lower than an impurity concentration of the drain region.

10. The method according to claim 9, wherein a dose of the ion implantation is substantially uniform in a surface direction of the semiconductor layer.

11. The method according to claim 9, wherein
the mask includes a first opening formation region and a second opening formation region, the second opening formation region having an opening ratio per unit surface area lower than an opening ratio per unit surface area of the first opening formation region, and
the first semiconductor region is formed in the semiconductor layer below the first opening formation region and the second semiconductor region is formed in the semiconductor layer below the second opening formation region.

12. The method according to claim 11, wherein the second opening formation region further includes
a first region adjacent to the first opening formation region, and
a second region positioned at a side of the first region opposite to the first opening formation region, the second region having an opening ratio per unit surface area lower than an opening ratio per unit surface area of the first region.

13. The method according to claim 11, wherein the second opening formation region further includes
a first region adjacent to the first opening formation region, and
a second region positioned at a side of the first region opposite to the first opening formation region, the second region having a film thickness thicker than a film thickness of the first region.

14. A method for manufacturing a semiconductor device, comprising:
selectively performing ion implantation into a semiconductor layer using a mask to simultaneously form a first semiconductor region of a second conductivity type and a second semiconductor region of the second conductivity type in the semiconductor layer, the second semiconductor region having a second conductivity type impurity concentration higher than a second conductivity type impurity concentration of the first semiconductor region;
performing ion implantation uniformly into an entire surface of the first semiconductor region and the second semiconductor region to simultaneously form a third semiconductor region of a first conductivity type on the first semiconductor region and a fourth semiconductor region of the first conductivity type on the second semiconductor region, the fourth semiconductor region having a first conductivity type impurity concentration lower than a first conductivity type impurity concentration of the third semiconductor region;
forming a gate electrode on the semiconductor layer via an insulating film;
forming a source region of the second conductivity type on the third semiconductor region;
forming a drain region of the second conductivity type on the fourth semiconductor region at a side of the gate electrode opposite to the source region; and
forming a drift region of the second conductivity type in a surface side portion of the semiconductor layer between the gate electrode and the drain region, the drift region being in contact with the drain region and having an impurity concentration lower than an impurity concentration of the drain region.
